(19) United States
(12) Patent Application Publication
(10) Pub. No.: US 2005/0196901 A1
(43) Pub. Date: Sep. 8, 2005

(54) Device mounting method and device transport apparatus

(76) Inventor: Kazuhiko Suzuki, Usuda-machi (JP)

Correspondence Address: HARNESS, DICKEY & PIERCE, P.L.C., P.O. BOX 828, BLOOMFIELD HILLS, MI, 48303, US

(21) Appl. No.: 11/054,413

(22) Filed: Feb. 9, 2005

(30) Foreign Application Priority Data
Mar. 5, 2004 (JP) 2004-062245

(51) Int. Cl. H01L 21/66; G01R 31/26; H01L 21/44; H01L 21/48; H01L 21/50

(52) U.S. Cl. 438/114; 438/113

(57) ABSTRACT

A device can be easily mounted on a circuit board. The device mounting method comprises a step in which devices 1 that are diced on a dicing sheet and have connection terminals 11 formed on the side not having the dicing sheet are collectively transferred to a transfer substrate on which an adhesive has been coated, and a step in which each device 1 is picked up from the transfer substrate and mounted on a circuit board 2.

### CROSS REFERENCE TO RELATED APPLICATION

The entire disclosure of Japanese Patent Application No. 2004-062245 filed Mar. 5, 2004 is hereby incorporated by reference.

### BACKGROUND OF THE INVENTION

1. Field of the Invention

Priority is claimed on Japanese Patent Application No. 2004-62245, filed Mar. 5, 2004, the contents of which are incorporated herein by reference.

The present invention relates to a device mounting method and a device transport apparatus.

2. Description of the Related Art

In order to mount semiconductor chips or other devices on a circuit board, protruding bumps (connection terminals) composed of electrically conductive members are provided on the semiconductor chips, for example. The semiconductor chips are fixed on the circuit board by bonding the bumps to the circuit board as disclosed in, for example, Japanese Patent Publication No. 2000-124245.

These types of semiconductor chips are formed by dividing or dicing a semiconductor wafer, which is made of silicon and so forth, placed on a dicing sheet. Each semiconductor chip is then handled by being suctioned to and held on the head of a facedown bonder having a vacuum suction port, and then bonded to the circuit board held on a stage.

The bumps of the semiconductor chips are normally formed on the semiconductor wafer on the side opposite to that facing the dicing sheet. When bonding the semiconductor chips on the circuit board, therefore, it is necessary to pick up the semiconductor chips and replace them on a tray or such with the side on which the bumps are formed facing downward. After that, the semiconductor chips are suctioned and held by the head of the bonder and picked up from the tray to be mounted on the circuit board. Consequently, there are cases in which the bumps of the semiconductor chips are damaged when the bumps make contact with the tray. In addition, in mounting methods of the conventional art, the semiconductor chips are handled manually or by a handler having an inverting mechanism when picking up the semiconductor chips and housing them in the tray. In the conventional methods, it is difficult to handle the semiconductor chips whose size is extremely small (e.g., measuring about 0.5 mm×0.5 mm), thereby resulting in cases in which the semiconductor chips were failed to be housed in the tray.

### SUMMARY OF THE INVENTION

In consideration of the aforementioned shortcomings, an object of the present invention is to allow devices to easily be mounted on a circuit board.

In order to achieve the aforementioned object, a device mounting method according to the present invention comprises a step in which devices that are diced on a dicing sheet and provided with connection terminals or bumps formed on one side opposite to the other side facing the dicing sheet are collectively transferred to a transfer substrate on which an adhesive is coated, and a step in which the devices are picked up from the transfer substrate and mounted on a circuit board.

According to the device mounting method of the present invention as described above, the devices diced on a dicing sheet are transferred to the transfer substrate coated with an adhesive, and then the devices are picked up from the transfer substrate and mounted on a printed board. Consequently, according to the device mounting method of the present invention, the devices can be easily inverted collectively by inverting the transfer substrate. That is, it is not necessary to invert or turn each device upside down after the device is picked up from the transfer substrate in order to mount the devices on the circuit board. Thus, the devices can be easily mounted on the circuit board.

In addition, according to the device mounting method of the present invention, the side of the devices on which the connection terminals are formed makes contact with the adhesive coated on the transfer substrate and, therefore, damage to the connection terminals can be prevented.

In addition, in the device mounting method of the present invention, a thermoplastic resin can be employed as the aforementioned adhesive.

The adhesive usually remains adhering to the connection terminals of the devices after the devices are picked up from the transfer substrate. By using the thermoplastic resin for the adhesive, the adhesive can be used as underfill that is filled between the devices and the circuit board.

In addition, in the device mounting method according to the present invention, solder can be employed as the aforementioned adhesive.

As mentioned above, the adhesive usually remains adhering to the connection terminals of the devices after the devices are picked up from the transfer substrate. By using solder for the adhesive, an intermetallic compound can easily be formed between the connection terminals and circuit board when mounting the devices to the circuit board.

Next, a device transport apparatus of the present invention for transferring devices to a predetermined location in which the devices are diced on a dicing sheet and have connection terminals formed on the side opposite to the dicing sheet, comprises a transfer substrate that is coated with an adhesive and to which the devices are collectively transferred from the dicing sheet, and a transfer substrate transport unit that transfers the transfer substrate.

According to the transport apparatus of the present invention, the devices that have been diced on a dicing sheet are collectively transferred to the transfer substrate after which that transfer substrate is transported. Consequently, the devices can easily be mounted on a circuit board by picking up each device from the transfer substrate thus transferred.

In addition, the transport apparatus of the present invention is preferably provided with a transfer substrate inversion unit that inverts or turn the transfer substrate upside down.

The transfer substrate inversion unit enables the transfer substrate to be transported in the inverted state and, therefore, the devices can be mounted on a circuit board more easily.

### BRIEF DESCRIPTION OF THE DRAWINGS

FIG. 1 is a schematic drawing showing the overall constitution of a circuit board on which a micro-semiconductor chip is mounted.

FIGS. 2A to 2F are sectional views for explaining a device mounting method according to a first embodiment of the present invention.

FIG. 3 is a perspective view of a transfer substrate used in the first embodiment of the present invention.

FIGS. 4A to 4C are sectional views for explaining a device mounting method according to a second embodiment of the present invention.

FIG. 5 is a block diagram showing a control system of a transport apparatus according to a third embodiment of the present invention.

### DETAILED DESCRIPTION OF THE PREFERRED EMBODIMENTS

The following provides an explanation of embodiments of the device mounting method and transport apparatus of the present invention with reference to the drawings. It is to be noted that the scale of each member in the following drawings is suitably changed to make each member of a recognizable size.

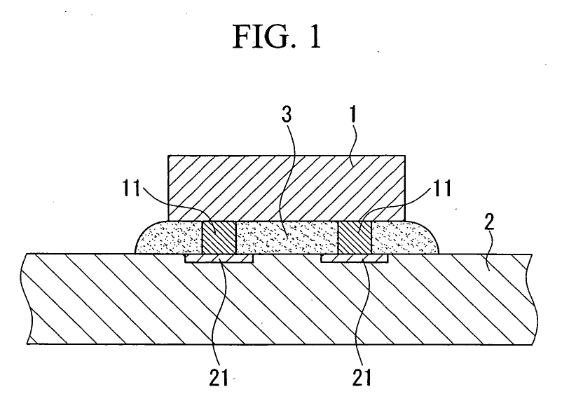

FIG. 1 is a schematic drawing showing the overall constitution of a circuit board 2 on which a micro-semiconductor chip (device) 1 is mounted. As shown in the drawing, a plurality of bumps I (connection terminals) are formed on one side of micro-semiconductor chip 1, and each bump 11 is connected to a conductor 21 of a circuit board 2. An underfill 3 is arranged between micro-semiconductor chip 1 and circuit board 2 to protect bumps 11. The underfill 3 is formed by a thermoplastic resin. A surface emitting laser device, for example, measuring about 0.5×0.5 mm in size is used for the micro-semiconductor chip 1.

Next, an explanation of a mounting method for mounting the micro-semiconductor chip 1 on circuit board 2 according to a first embodiment will be made hereinafter.

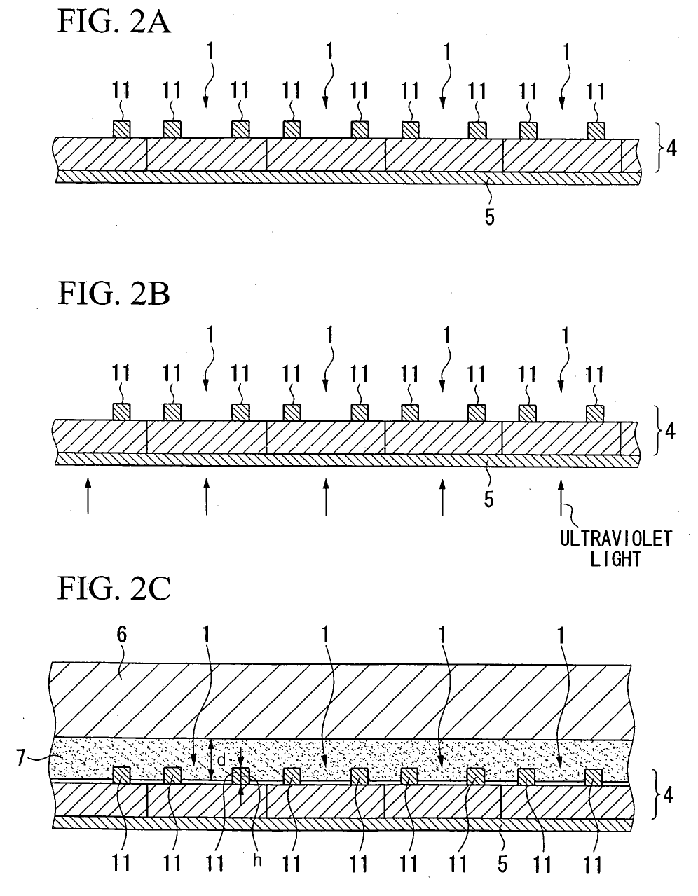

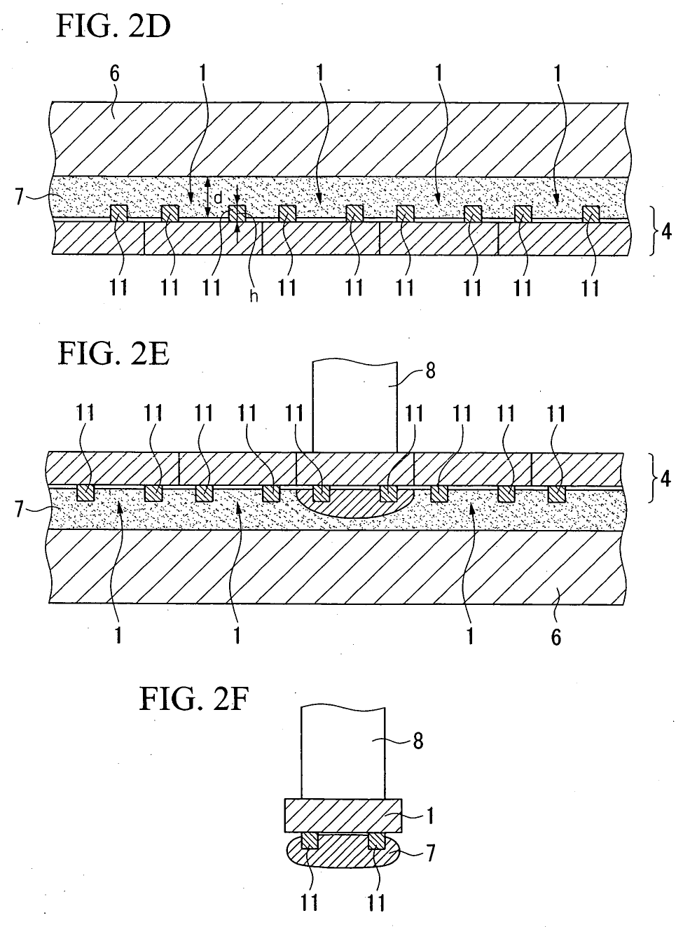

First, as shown in FIG. 2A, a semiconductor wafer 4 composed of silicon and so forth is arranged on a dicing sheet 5 coated with an ultraviolet-cured resin. The semiconductor wafer 4 is divided into a plurality of sections by a diamond blade or laser beam to form micro-semiconductor chips 1. Subsequently, as shown in FIG. 2B, the ultraviolet light is irradiated from the lower side, that is, from the side where the dicing sheet 5 is provided. The adhesive strength of the ultraviolet-cured resin is thus reduced by irradiating with the ultraviolet light. A plurality of bumps 11 corresponding to each micro-semiconductor chip 1 are formed in advance on the side of semiconductor wafer 4 not having a dicing sheet. More specifically, a plurality of bumps 11 are provided on the upper side of the semiconductor wafer 4 in the drawing, that is, the bumps 11 are provided on the side opposite to the lower side of the wafer 4 on which the dicing sheet 5 is provided. In addition, various semiconductor devices, electronic circuits and so forth are formed in advance on semiconductor wafer 4.

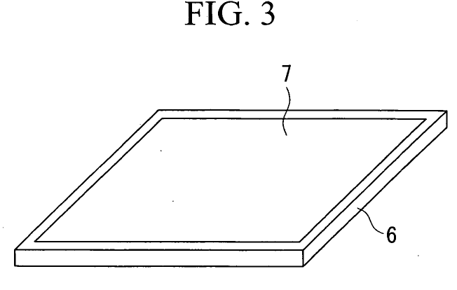

Next, as shown in FIG. 2C, a transfer substrate 6 is pressed against the semiconductor wafer 4 on the dicing sheet 5 while heating. As shown in FIG. 3, the transfer substrate 6 is provided with a thermoplastic resin 7 which is uniformly coated onto one side of this transfer substrate 6. The side of the transfer substrate 6 on which the thermoplastic resin 7 is coated is then pressed against the semiconductor wafer 4. The transfer substrate 6 is preferably formed from a member having rigidity, and can be formed from, for example, ceramics. In addition, thickness d of the thermoplastic resin 7 coated on the transfer substrate 6 is preferably greater than height h of the bumps 11 formed on each of the micro-semiconductor chips 1. By making thickness d of the thermoplastic resin 7 greater than height h of the bumps 11 in this manner, the bumps 11 can be prevented from directly contacting the transfer substrate 6, thereby making it possible to prevent damage to the bumps 11.

Subsequently, the transfer substrate 6 is cooled. As a result of cooling the transfer substrate 6, the thermoplastic resin 7 is hardened and the micro-semiconductor chips I are collectively transferred from the dicing sheet 5 to the transfer substrate 6 by dissociating the dicing sheet 5 from the semiconductor chips 1 and the transfer substrate 6 as shown in FIG. 2D. As a result of irradiating the dicing sheet 5 with the ultraviolet light as previously described, the micro-semiconductor chips 1 are easily transferred to the transfer substrate 6 since the adhesive strength of the ultraviolet-cured resin coated on the dicing sheet 5 is decreased.

After inverting the transfer substrate 6 to which micro-semiconductor chips 1 have been collectively transferred, the micro-semiconductor chips 1 with the transfer substrate 6 are transported to a bonding apparatus that mounts the micro-semiconductor chips 1 on the circuit board 2. As is apparent, it is extremely easy to invert the transfer substrate 6 to which the micro-semiconductor chips 1 have been collectively transferred in this manner as compared with inverting each of the micro-semiconductor chips 1, and the risk of error is extremely low. Consequently, the micro-semiconductor chips 1 can be reliably inverted according to the device mounting method of the present embodiment.

Next, each of the micro-semiconductor chips 1 transferred to the transfer substrate 6 will be mounted on the circuit board 2 by a head 8 equipped with a bonding apparatus. The head 8 holds the micro-semiconductor chips 1 by vacuum suction, and has a vacuum suction mechanism and a heating mechanism.

As shown in FIG. 2E, the head 18 makes contact with one of the micro-semiconductor chips 1 and then the single micro-semiconductor chip 1 is suctioned to the head 8. Here, since the head 8 has the heating mechanism, the thermoplastic resin 7 that surrounds the micro-semiconductor chip 1 is softened by the heating mechanism of the head 8. Consequently, one of the micro-semiconductor chips 1 can be easily dissociated from the transfer substrate 6. Furthermore, when the micro-semiconductor chip 1 is dissociated from the transfer substrate 6, the thermoplastic resin 7 remains adhered to the micro-semiconductor chip 1 as shown in FIG. 2F.

According to the device mounting method of the present embodiment thus described, since the micro-semiconductor chips 1 are transferred to the transfer substrate 6 that has been coated with the thermoplastic resin 7 in this manner, the bumps 11 of the micro-semiconductor chips 1 do not make direct contact with a tray and so forth. Consequently, the micro-semiconductor chips 1 can be easily inverted while preventing damage to the bumps 11.

After that, the bumps 11 of the micro-semiconductor chip 1 are connected with conductors 21 of the circuit board 2 by moving the head 8 over a predetermined location of the circuit board 2 and heating and pressing the micro-semiconductor chip 1 against the circuit board 2. Here, since thermoplastic resin adhered to micro-semiconductor chip 1 is heated and softened by the heating mechanism of the head 8, the bumps 11 of the micro-semiconductor chip 1 and the conductors 21 of the circuit board 2 can be easily contacted directly by pressing the micro-semiconductor chip 1 against circuit board 2.

The micro-semiconductor chip 1 is then mounted on circuit board 2 by dissociating the head 8 from the micro-semiconductor chip 1 and then hardening the thermoplastic resin 7 by cooling. In addition, the thermoplastic resin 7 can also be used as an underfill 3 as a result of being hardened. As a result of using the thermosetting resin 7 as an adhesive coated onto the transfer substrate 6 in this manner, it is not necessary to fill an additional underfiller between the micro-semiconductor chip 1 and the circuit board 2 after having bonded the micro-semiconductor chip 1 to the circuit board 2.

According to the device mounting method of the first embodiment, the micro-semiconductor chips 1 that have been diced on the dicing sheet 5 are transferred to the transfer substrate 6 on which the thermoplastic resin 7 has been coated and, thereafter, the micro-semiconductor chips 1 are picked up from the transfer substrate 6 to be mounted on the circuit board 2. Since the micro-semiconductor chips 1 can be collectively inverted by inverting the transfer substrate 6, it is not necessary to invert each micro-semiconductor chip 1 during the time from when the micro-semiconductor chips 1 are picked up from the transfer substrate 6 to the time they are mounted on the circuit board 2. Thus, the micro-semiconductor chips 1 can be easily mounted on circuit board 2.

Next, an explanation will be provided of a device mounting method according to a second embodiment of the present invention hereinafter. In the following description, explanations of those sections of the second embodiment that are similar to the aforementioned first embodiment are omitted for the sake of simplicity.

The device mounting method of the second embodiment differs from the aforementioned first embodiment in that a solder is used for the adhesive coated onto the transfer substrate. Furthermore, the solder used in the second embodiment is the lead-free solder.

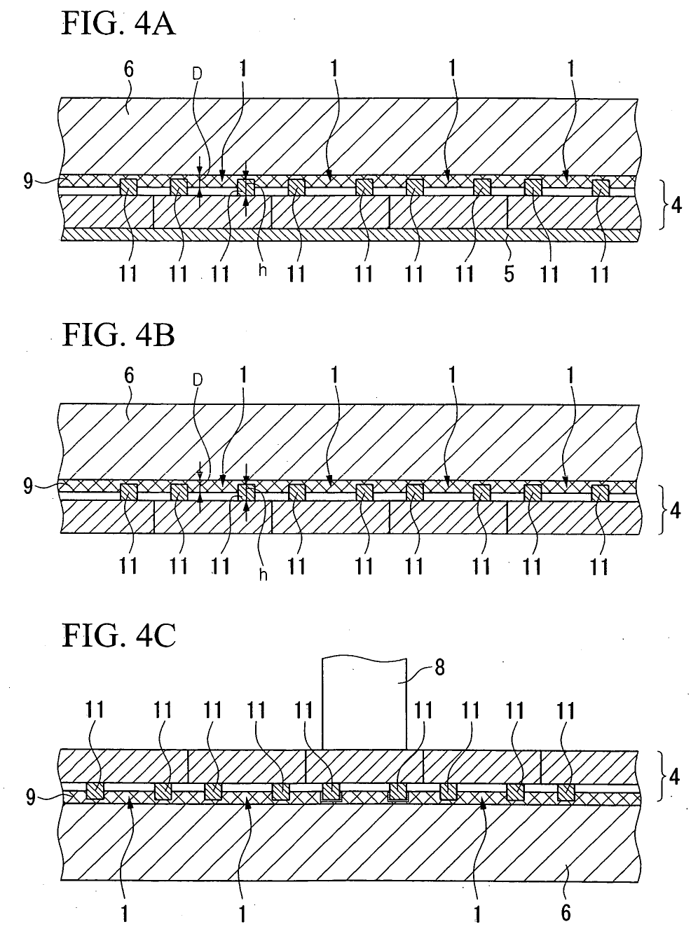

In the device mounting method of the second embodiment, as shown in FIG. 4A, a transfer substrate 6 coated with solder 9 is pressed against the semiconductor wafer 4 attached with the dicing sheet 5. When pressing the transfer substrate 6 against the semiconductor wafer 4, the solder 9 is softened by heating the transfer substrate 6 to a degree that it does not run off when the transfer substrate 6 is inverted. Thickness D of the solder 9 is coated on the transfer substrate 6 by preferably less than the height h of the bumps 11 possessed by each micro-semiconductor chip 1. By making the thickness D of the solder 9 less than the height h of the bumps 11 in this manner, short-circuiting between the circuit of the micro-semiconductor chips 1 and adjacent bumps 11 can be inhibited. By pressing the transfer substrate 6 coated with solder 9 against the semiconductor wafer 4 in this manner, an intermetallic compound is formed on the surface of the bumps 11.

Subsequently, the transfer substrate 6 is cooled. As a result of cooling the transfer substrate 6, the solder 9 is hardened and the micro-semiconductor chips 1 are collectively transferred from the dicing sheet 5 to the transfer substrate 6 by dissociating the dicing sheet 5 from the semiconductor wafer 4 and the transfer substrate 6 as shown in FIG. 4B. After inverting the transfer substrate 6 to which micro-semiconductor chips 1 have been collectively transferred, the micro-semiconductor chips 1 together with the transfer substrate 6 are transported to the bonding apparatus that mounts the micro-semiconductor chips 1 on the circuit board 2.

As shown in FIG. 4C, the head 18 makes contact with one of the micro-semiconductor chips 1 and then the single micro-semiconductor chip 1 is suctioned to the head 8. Since the head 8 has the heating mechanism, the solder 9 that surrounds the micro-semiconductor chip 1 is softened as a result of head 8 making contact with the micro-semiconductor chip 1. Consequently, the micro-semiconductor chips 1 can be easily dissociated from the transfer substrate 6. When the micro-semiconductor chip 1 is dissociated from the transfer substrate 6, the intermetallic compound is formed on the surface of the bumps 11 of the micro-semiconductor chip 1.

Subsequently, the bumps 11 of the micro-semiconductor chip 1 are connected with conductors 21 of the circuit board 2 by moving the head 8 over a predetermined location of the circuit board 2 and by heating and pressing the micro-semiconductor chip 1 against the circuit board 2.

The micro-semiconductor chip 1 is then mounted on the circuit board 2 by dissociating the head 8 from the micro-semiconductor chip 1 and then filling the underfill 3 between the micro-semiconductor chip 1 and the circuit board 2.

According to the device mounting method of the second embodiment in this manner, the micro- semiconductor chips 1 can easily be collectively inverted by inverting the transfer substrate 6. Therefore, it is not necessary to invert each micro-semiconductor chip 1 during the time from when the micro-semiconductor chips 1 are picked up from the transfer substrate 6 to the time they are mounted on the circuit board 2, and the micro-semiconductor chips 1 can be easily mounted on circuit board 2.

Next, an explanation will be provided of a device transport apparatus, as a third embodiment of the present invention, which is used for performing the device mounting method according to the aforementioned first or second embodiment.

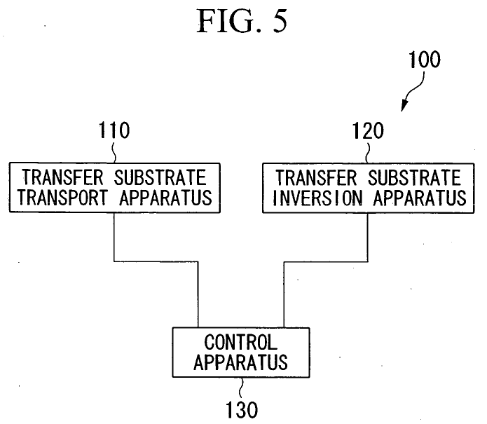

FIG. 5 is a block diagram that represents a control system of a transport apparatus 100 of the third embodiment. The transport apparatus 100 is provided with a transfer substrate transport apparatus 110 (transfer substrate transport unit) that transports the transfer substrate 6 shown in the aforementioned first and second embodiments, a transfer substrate inversion apparatus 120 (transfer substrate inversion unit) that inverts transfer substrate 6, and a control apparatus 130 that controls the transfer substrate transport apparatus 110 and the transfer substrate inversion apparatus 120, and as shown in FIG. 5. The transfer substrate transport apparatus 110 and the transfer substrate inversion apparatus 120 are electrically connected with the control apparatus 130, respectively. In the case of using transport apparatus 100 to carry out the device mounting method of the aforementioned first embodiment, the thermoplastic resin 7 is coated onto the transfer substrate 6, while in the case of using transport apparatus 100 to carry out the device mounting method of the aforementioned second embodiment, the solder 9 is coated onto the transfer substrate 6.

The control apparatus 130 enables the transfer substrate transport apparatus 110 to move (transport) the transfer substrate 6 over the semiconductor wafer 4 and, after that, to move (transport) the substrate 6 so as to press the substrate 6 against the semiconductor wafer 4.

Next, the control apparatus 130 makes the transfer substrate transport apparatus 110 to dissociate the semiconductor wafer 4 and the transfer substrate 6 from the dicing sheet 5 on which the semiconductor wafer 4 had been provided. Subsequently, the control apparatus 130 drives the transfer substrate transport apparatus 110 so as to transport the transfer substrate 6 to a bonding apparatus shown in the aforementioned first embodiment and second embodiment. After that, the control apparatus 130 controls the transfer substrate inversion apparatus 120 to drive the transfer substrate 6 to be inverted.

According to the device transport apparatus 100 of the third embodiment, the transport apparatus 100 is provided with the transfer substrate transport apparatus 110 that transports the transfer substrate 6. The micro-semiconductor chips 1 can be, therefore, easily transferred to the transfer substrate 6, and additionally transported to the bonding apparatus.

In addition, according to the transport apparatus 100 of the third embodiment, the transport apparatus 100 is provided with the transfer substrate inversion apparatus 120. Therefore, the transfer substrate 6 to which the micro-semiconductor chips 1 have been transferred can be transported to the bonding device after being inverted.

While the preferred embodiments of the device mounting method and the device transport apparatus according to the present invention have been described and illustrated above, it should be understood that these are exemplary of the present invention and are not to be considered as limiting.

The shapes, combinations and so forth of composite members shown in the aforementioned embodiments are merely examples, and various changes can be made based on design requirements and so forth without departing from the spirit or scope of the present invention.

For example, the adhesive-coated region of the transfer substrate 6 may be divided into a plurality of regions by partitions and so forth. By dividing the adhesive-coated region of transfer substrate 6 into a plurality of regions in this manner, the amount of the thermoplastic resin that adheres to the bumps 11 can be easily adjusted in the case of, for example, using the thermoplastic resin for the adhesive.

1. A device mounting method comprising the steps of:
collectively transferring a plurality of devices to a transfer substrate on which an adhesive is coated, said devices being diced on a dicing sheet and provided with connection terminals formed on one side opposite to the other side that faces said dicing sheet; and
picking up said devices from said transfer substrate to mount said devices on a circuit board.

2. The device mounting method according to claim 1, wherein said adhesive is a thermoplastic resin.

3. The device mounting method according to claim 1, wherein the adhesive is solder.

4. A device transport apparatus for transferring a plurality of devices to a predetermined location, said devices being diced on a dicing sheet and having connection terminals formed on one side opposite to the other side that faces said dicing sheet, comprising:
a transfer substrate coated with an adhesive, said devices being collectively transferred from said dicing sheet to said transfer substrate; and
a transfer substrate transport unit for transferring said transfer substrate to said predetermined location.

5. The transport apparatus according to claim 4, further comprising a transfer substrate inversion unit that inverts the transfer substrate.
